(19) United States
(12) Patent Application Publication
(10) Pub. No.: US 2013/0269743 A1
(43) Pub. Date: Oct. 17, 2013

(54) THERMOELECTRIC POWER GENERATION MODULE

(71) Applicant: Kenichi Tajima, Kirishima-shi (JP)

(72) Inventor: Kenichi Tajima, Kirishima-shi (JP)

(21) Appl. No.: 13/997,505

(22) PCT Filed: Dec. 22, 2011
(86) PCT No.: PCT/JP2011/079861

§ 371 Date: Jun. 24, 2013

(30) Foreign Application Priority Data
Dec. 24, 2010 (JP) 2010-288123

(51) Int. Cl. H01L 35/30

(52) U.S. Cl. CPC H01L 35/30
USPC 136/205

(57) ABSTRACT

A piezoelectric vibration element capable of reducing occurrence of unnecessary vibration, and a piezoelectric vibration device and a portable terminal using the same are disclosed. The piezoelectric vibration element includes a plurality of electrode layers and a plurality of piezoelectric layers being stacked along a first direction, the piezoelectric vibration element having two surfaces that face each other to be at intervals in the first direction, and vibrating in bending mode in the first direction with an amplitude varying along a second direction perpendicular to the first direction according to input of an electric signal, one of the two surfaces having such a shape that a central portion thereof in a third direction perpendicular to the first direction and the second direction protrudes as compared with opposite end portions thereof in the third direction.

### TECHNICAL FIELD

The present invention relates to a thermoelectric power generation module that converts temperature differences into electricity. More particularly, the present invention relates to a thermoelectric power generation module that is suitably used in converting sunlight into heat and further into electricity.

### BACKGROUND ART

Thermoelectric elements make use of the Peltier effect and the Seebeck effect. The Peltier effect is an effect in which, when electric current is caused to flow through a p-n junction pair formed by a p-type semiconductor (P-type thermoelectric element) and an n-type semiconductor (N-type thermoelectric element), heat is generated at one end of each semiconductor, and heat is absorbed at the other end of each semiconductor. The Seebeck effect is, on the contrary, an effect in which temperature differences at a p-n junction pair cause an electromotive force to be generated. Thermoelectric modules making use of the Peltier effect are capable of precisely controlling temperature, are small, have a simple structure, and are widely used in, for example, chlorofluorocarbon-free cooling devices, cooling devices of, for example, photodetectors and semiconductor manufacturing devices, and temperature regulators of laser diodes. In thermoelectric power generation modules making use of the Seebeck effect, electric current flows when a temperature difference exists between both ends thereof. Therefore, they are also expected to be used in power generators for, for example, exhaust heat recovery power generation.

As a thermoelectric module, for example, the following type of thermoelectric module is known. This type is formed by electrically connecting a P-type thermoelectric element and an N-type thermoelectric element in series, arranging the P-type thermoelectric element and the N-type thermoelectric element between a pair of supporting substrates each having a wire conductor on one of principal surfaces thereof, joining the wire conductors to the P-type thermoelectric element and the N-type thermoelectric element using solder, and bonding a metallic plate or a heat exchanger on the other principal surface of each supporting substrate using a joining material. (Refer to, for example, PTL 1.)

As a thermoelectric power generation module that generates electric power by making use of the heat of sunlight, a thermoelectric conversion device in which a solar collector is mounted to a high-temperature-side supporting substrate is proposed. (Refer to, for example, PTL 2.)

### CITATION LIST

### Patent Literature

[PTL 1] Japanese Unexamined Patent Application Publication No. 2006-234250

[PTL 2] Japanese Unexamined Patent Application Publication No. 4-139773

### SUMMARY OF INVENTION

### Technical Problem

Thermoelectric power generation modules tend to be deformed due to a temperature difference between a pair of supporting substrates, that is, between the high-temperature-side supporting substrate and the low-temperature-side supporting substrate. Here, since thermoelectric materials that form a P-type thermoelectric element and an N-type thermoelectric element are basically fragile materials, the P-type thermoelectric element and the N-type thermoelectric element may break by the deformation of the thermoelectric power generation module. In particular, when the area is made large for increasing thermoelectric conversion efficiency (power generation efficiency), the thermoelectric power generation module may no longer be capable of withstanding use over a long period of time.

In view of the above-described circumstances, it is an object of the present invention to provide a thermoelectric power generation module having excellent durability.

### Solution to Problem

A thermoelectric power generation module according to the present invention includes a pair of supporting substrates that oppose each other, wire conductors at opposing inner-side principal surfaces of the pair of supporting substrates, thermoelectric elements arranged between the opposing inner-side principal surfaces of the pair of supporting substrates, and a heat collecting member mounted on an outer-side principal surface of one of the supporting substrates, wherein a plurality of uneven portions or a plurality of grooves are formed at a contact surface of the heat collecting member that contacts the supporting substrate.

According to the thermoelectric power generation module of the present invention, in the above-described structure, the heat collecting member is a plate-shaped transparent body.

### Advantageous Effects of Invention

By forming uneven portions or grooves at the principal surface of the heat collecting member that contacts the supporting substrate, it is possible to reduce concentration of thermal stress on the heat collecting member and increase durability (thermal shock resistance).

### BRIEF DESCRIPTION OF DRAWINGS

FIG. 1 is an exploded perspective view of a thermoelectric power generation module according to an embodiment of the present invention.

FIG. 2 is a schematic sectional view of the thermoelectric power generation module shown in FIG. 1.

FIG. 3 is a partial transparent plan view showing the relationship between the positions of grooves and the positions of thermoelectric elements shown in FIG. 2.

FIG. 4(a) is a schematic sectional view of another exemplary heat collecting member, and FIG. 4(b) is a bottom view of the heat collecting member shown in FIG. 4(a).

FIG. 5(a) is a schematic sectional view of another exemplary heat collecting member, and FIG. 5(b) is a bottom view of the heat collecting member shown in FIG. 5(a).

### DESCRIPTION OF EMBODIMENTS

A thermoelectric power generation module according to an embodiment of the present invention is hereunder described on the basis of the drawings.

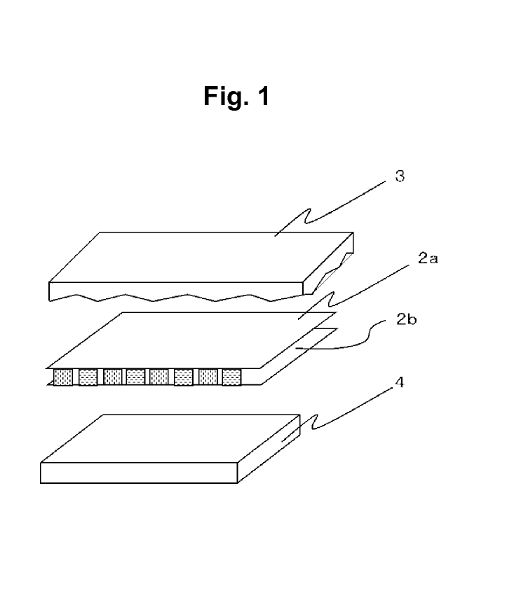

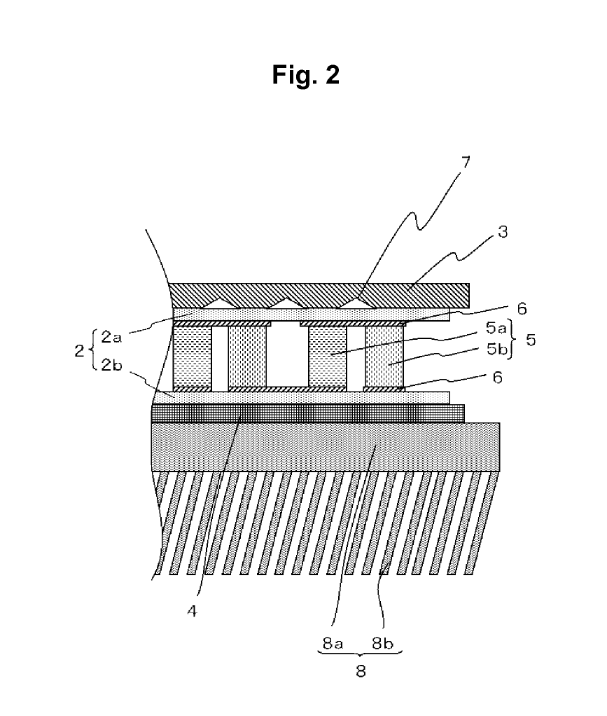

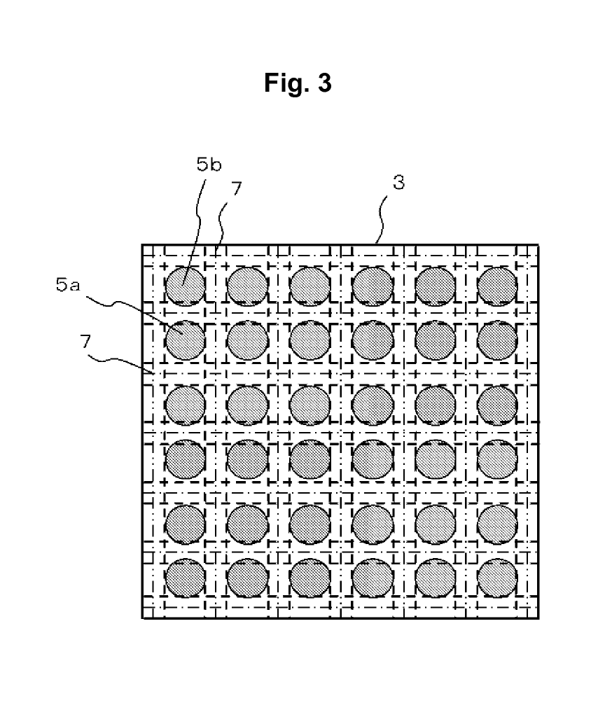

FIG. 1 is an exploded perspective view of a thermoelectric power generation module according to an embodiment of the present invention. FIG. 2 is a schematic sectional view of the thermoelectric power generation module shown in FIG. 1. FIG. 3 is a partial transparent plan view showing the relationship between the positions of grooves and the positions of thermoelectric elements shown in FIG. 2.

The thermoelectric power generation module according to the present invention includes a pair of supporting substrates 2 (2a, 2b) that oppose each other, wire conductors 6 at opposing inner-side principal surfaces of the pair of supporting substrates 2, thermoelectric elements 5 (5a, 5b) between the opposing inner-side principal surfaces of the pair of supporting substrates 2, and a heat collecting member 3 mounted on an outer-side principal surface of the supporting substrate 2a of the pair of supporting substrates 2. In the thermoelectric power generation module, a plurality of uneven portions or a plurality of grooves 7 are formed at a contact surface of the heat collecting member 3 that contacts the supporting substrate 2a.

The pair of supporting substrates 2 are, for example, substrates in which copper plates (for example, copper plates having a thickness of from 100 to 500 μm) are bonded to outer-side principal surfaces of epoxy resin plates to which an alumina filler is added. The supporting substrates 2a and 2b are disposed so as to oppose each other. The dimensions of the pair of supporting substrates 2 in plan view are, for example, 40 to 250 mm in a vertical direction and 40 to 250 mm in a horizontal direction. The thicknesses of the pair of supporting substrates 2 are, for example, 0.05 to 2.0 mm. In particular, since a high electric power can be obtained when the area is large, it is desirable that each supporting substrate 2 have a large area of, for example, at least 200 mm×200 mm. Each supporting substrate 2 may be formed of a ceramic material such as alumina or aluminum nitride.

The wire conductors 6 are provided at the opposing inner-side principal surfaces of the pair of supporting substrates 2 (2a, 2b). The wire conductors 6 are, for example, formed into wire patterns by etching copper plates that are bonded to the inner-side principal surfaces of the pair of supporting substrates 2. The wire conductors 6 are provided for electrically connecting in series N-type thermoelectric elements 5a and P-type thermoelectric elements 5b that are adjacent to each other. The materials for forming the wire conductors 6 include not only copper but also, for example, silver and silver-palladium.

The thermoelectric elements 5 (N-type thermoelectric elements 5a, P-type thermoelectric elements 5b) are arranged between the opposing inner-side principal surfaces of the pair of supporting substrates 2 (2a, 2b).

The main body of each of the thermoelectric elements 5 (N-type thermoelectric elements 5a, P-type thermoelectric elements 5b) is formed of a thermoelectric material containing A2B3 (A represents Bi and/or Sb, and B represents Te and/or Se), and is desirably formed of a bismuth (Bi) based or a tellurium (Te) based thermoelectric material. More specifically, each N-type thermoelectric element 5a is formed of, for example, a thermoelectric material containing a solid solution of Bi₂Te₃ (bismuth telluride) and Bi₂Se₃ (bismuth selenide); and each P-type thermoelectric element 5b is formed of, for example, a thermoelectric material containing a solid solution of Bi₂Te₃ (bismuth telluride) and Sb₂Te₃ (antimony telluride).

Here, the thermoelectric material of each N-type thermoelectric element 5a is one in which an N-type formation material containing Bi, Te, and Se that has been melted and solidified once is solidified in one direction by the Bridgman method and is formed into, for example, a rod body that has a diameter of from 1 to 3 mm and that is circular in cross section. The thermoelectric material of each P-type thermoelectric element 5b is one in which a P-type formation material containing Bi, Sb, and Te that has been melted and solidified once is solidified in one direction by the Bridgman method and is formed into, for example, a rod body that has a diameter of from 1 to 3 mm and that is circular in cross section.

After coating side surfaces of these thermoelectric materials with a resist that prevents plating adhesion, the coated side surfaces are cut to a width of, for example, 0.3 to 5.0 mm using a wire saw. In addition, when, by electroplating, an Ni layer is formed only on each of the cut surfaces and an Sn layer is formed thereon, and the resist is peeled off using a solution, the thermoelectric elements 5 (N-type thermoelectric elements 5a, P-type thermoelectric elements 5b) can be provided.

As shown in FIGS. 2 and 3, the thermoelectric elements 5 are arranged vertically and horizontally at an interval of, for example, 0.5 to 3 mm, or 0.5 to 2.0 times the size (diameter) of the thermoelectric elements.

Although the thermoelectric elements 5 (N-type thermoelectric elements 5a, P-type thermoelectric elements 5b) may have a circular cylindrical shape, a quadrangular prismatic shape, or a polygonal prismatic shape, it is desirable that they have a circular cylindrical shape to prevent the concentration of stress due to expansion and contraction during use.

The thermoelectric elements 5 (N-type thermoelectric elements 5a, P-type thermoelectric elements 5b) are electrically connected by being joined to the wire conductors 6 using solder paste that is applied in a pattern that is the same as those of the wire conductors 6.

The supporting substrate 2a of the pair of supporting substrates 2 is provided with the heat collecting member 3 that is mounted on an outer-side principal surface of the supporting substrate 2a. Examples of mounting methods include a securing method using screws, a method that combines screwing using screws and an adhesion effect resulting from a heat absorbing material (material having a high heat absorbing property)(described later), and a method using an epoxy resin or acrylic resin based adhesive having high weather resistance. However, the mounting method is not particularly limited. By providing the heat collecting member 3, it is possible to increase the rigidity of the thermoelectric power generation module by protecting the outer-side principal surface of the supporting substrate 2a.

The heat collecting member 3 is a substrate for assisting in heat collection to the high-temperature-side supporting substrate 2a of the pair of supporting substrates 2, and is formed to a thickness of, for example, 0.5 to 35.0 mm, and, desirably, 0.5 to 10.0 mm. As the heat collecting member 3, a heat collecting member having high thermal conductivity or low thermal conductivity is used in accordance with the heat collecting method. For example, a plate-shaped body formed of, for example, a semiconductor (such as glass, resin, ceramics, or silicon), a metal (such as SUS or aluminum), or a composite material containing a semiconductor (such as silicon), formed on a thin film on a glass substrate, and a metal (such as SUS or aluminum), formed on a thin film on a glass substrate, may be used.

Here, when the high-temperature-side supporting substrate 2a is heated by collecting sunlight, it is effective that the plate-shaped member be a plate-shaped transparent body from the viewpoint of power generation heat by passing sunlight and causing the sunlight to strike the supporting substrate 2a. Although the plate-shaped transparent body may be formed of glass, resin, or ceramics, it is desirable that the plate-shaped transparent body be formed of a material having low thermal conductivity, that is, it is desirable that the thermal conductivity be low. This is because heat at the high-temperature side is prevented from escaping, as a result of which the temperature can be made higher. Examples of materials having low thermal conductivity include transparent resin (such as glass and a transparent acrylic resin), single crystal sapphire, and ceramics having light transparency. However, vitreous material that easily passes sunlight therethrough is suitably used. Although this glass may be borosilicate glass or quartz glass, it is most desirable to use quartz glass in terms of characteristics. It is desirable that the transparency (transmittance expressed by percentage of a ratio between the intensity of incident light and the intensity of transmitted light) be, for example, 80 to 99%, and that the material be colorless and transparent from the viewpoint of increasing transmittance.

In addition, it is important that the plurality of uneven portions or the plurality of grooves 7 be formed at the contact surface of the heat collecting member 3 that contacts the supporting substrate 2a.

When the plurality of uneven portions or the plurality of grooves 7 are formed at the contact surface of the heat collecting member 3 that contacts the supporting substrate 2a, it is possible to increase durability (thermal shock resistance) by reducing the concentration of thermal stress generated by thermal shock, in addition to making it possible to increase the rigidity of the thermoelectric power generation module by protecting the outer-side principal surface of the supporting substrate 2a. In addition, when the heat collecting member 3 is a plate-shaped transparent body and uses and collects sunlight (heat of sunlight), such a form causes the absorption of heat to be increased by limiting reflection of sunlight that has passed through the heat collecting member 3. Therefore, since a large temperature difference exists at the pair of supporting substrates, it is possible to efficiently convert the sunlight into heat and increase the power generation efficiency of the thermoelectric power generation module. Further, by suitably setting the positions of the uneven portions or the grooves as described below, it is possible to obtain a larger temperature difference by distributing the heat of the sunlight that has been collected due to a lens effect to desired positions. This makes it possible for the area of the thermoelectric power generation module to be large.

The uneven portions or grooves are effective as long as they are not at least planar. More specifically, it is important that the uneven portions or grooves have a depth of 50 μm or more, more desirably, 100 μm or more, and even more desirably 200 μm or more.

FIGS. 2 and 3 each show a structure in which the grooves 7 that are V-shaped in cross section are provided vertically and horizontally along portions between N-type thermoelectric elements 5a and P-type thermoelectric elements 5b that are adjacent to each other. From the viewpoint of collecting sunlight when the heat collecting member 3 is a plate-shaped transparent body and uses and collects sunlight (heat of sunlight), it is desirable that widths of opening portions of the grooves 7 (intervals between broken lines shown in FIG. 3) correspond to distances that are ±30% of the intervals between the thermoelectric elements 5. For example, when the intervals between the thermoelectric elements 5 are 2 mm, it is desirable that the width of each groove 7 be 1.4 to 2.6 mm. It is desirable that the depth of each groove 7 here be 0.1 to 0.5 mm. The shape of each groove 7 is not limited to a V shape in cross section. The shape may be a U shape in cross section in which a center portion is deep. The U shape in cross section makes it possible to efficiently collect light.

Accordingly, it is desirable to form the grooves 7 or concave portions along portions between the thermoelectric elements 5. This is because, if they are formed along portions between the thermoelectric elements 5, in a temperature distribution of the thermoelectric power generation module when the heat collecting member 3 is a plate-shaped transparent body and uses and collects sunlight (heat of sunlight), a large temperature difference can be obtained because the surface temperatures at the thermoelectric elements 5 are increased by a lens effect. Furthermore, it is desirable that portions provided in correspondence with to the thermoelectric elements 5 be rough for limiting reflection of sunlight.

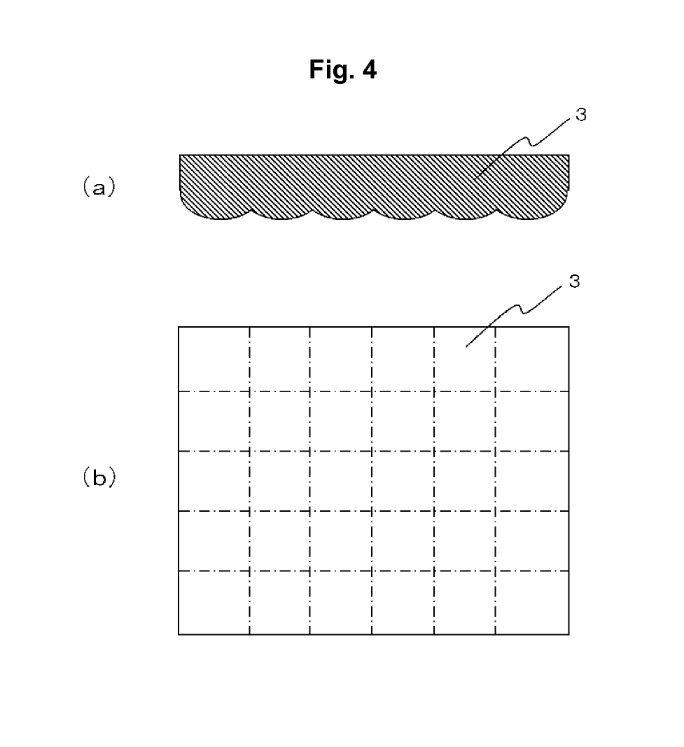

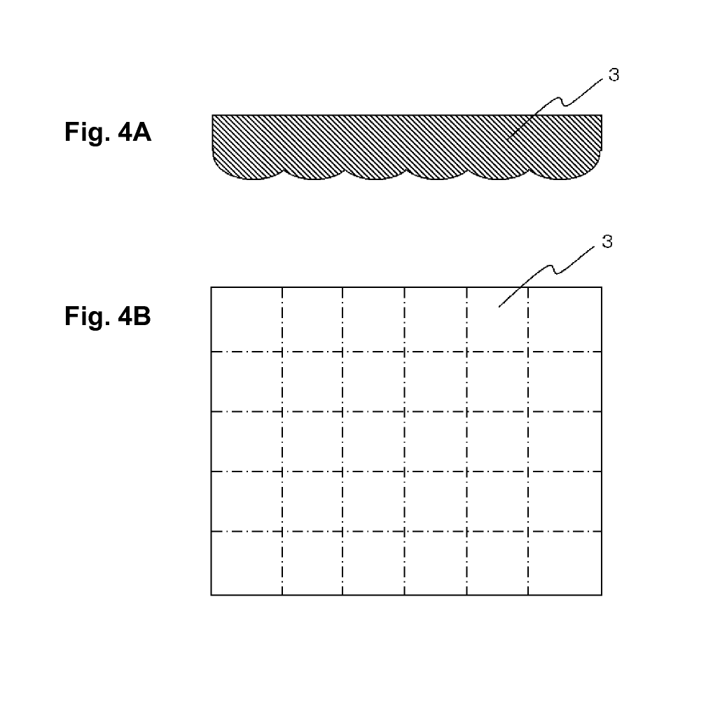

At the contact surface of the heat collecting member 3 that contacts the supporting substrate 2a, convex portions may be provided in correspondence with the arrangement of the thermoelectric elements 5. In other words, convex portions at an uneven surface of the heat collecting member 3 may be formed in correspondence with the arrangement of the thermoelectric elements 5. This is because, similarly to the reason above, when convex portions are formed in correspondence with the arrangement of the thermoelectric elements 5, in a temperature distribution of the thermoelectric power generation module, a large temperature difference can be obtained because the surface temperatures at the thermoelectric elements 5 are increased. For example, as shown in FIG. 4(a), such a heat collecting member 3 may be one in which a plurality of lens-like convex portions are provided on the principal surface of the heat collecting member 3 that becomes the contact surface that contacts the supporting substrate 2a and in which the opposite principal surface is flat. FIG. 4(b) is a bottom view of the heat collecting member 3 shown in FIG. 4(a), with long dashed lines indicating boundaries between the convex portions.

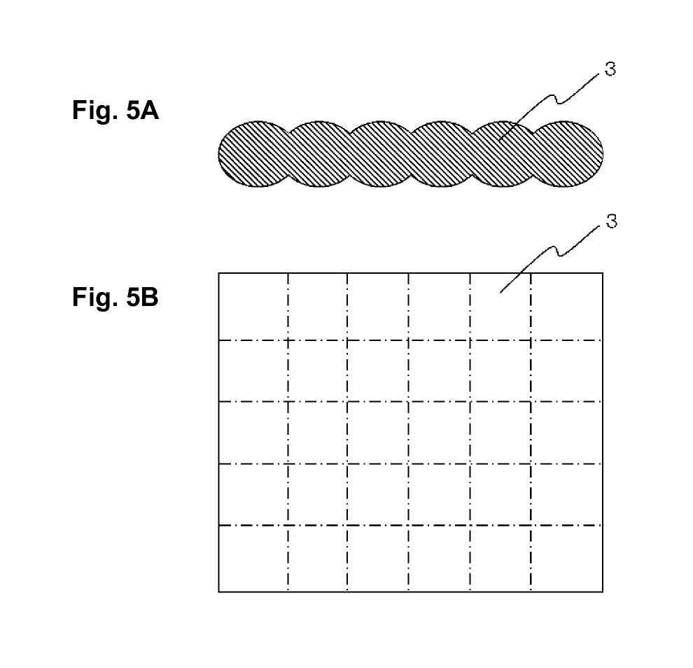

Further, it is desirable that the plurality of convex lens-like portions be disposed in correspondence with the arrangement of the thermoelectric elements 5 and be connected to each other. In other words, it is desirable that the convex portions shown in FIG. 4 be in the form of lenses. When sunlight (heat of sunlight) is used and collected, such a form makes it possible to increase temperature by further increasing collection efficiency. For example, as shown in FIG. 5(a), such a heat collecting member 3 may also be one in which the principal surface that becomes the contact surface that contacts the supporting substrate 2a and the opposite principal surface have convex lens-like portions that are disposed vertically and horizontally side by side and are connected to each other. FIG. 5(b) is a bottom view of the heat collecting member 3 shown in FIG. 5(a), with long dashed lines indicating boundaries between the convex lens-like portions.

In the thermoelectric power generation module according to the present invention, in order to further increase power generation efficiency, it is desirable that the outer-side principal surface of the supporting substrate 2a be provided with a covering layer formed of a heat absorbing material (material having a high heat absorbing property). As materials thereof, it is desirable to use black materials such as carbon, or materials that tend to absorb sunlight. By applying such materials, the temperature of the high-temperature side of the thermoelectric power generation module becomes higher and power generation efficiency is increased. In addition, due to the same reason, gaps (grooves 7 or concave portions) between the supporting substrate 2a and the heat collecting member 3 may be filled with a heat absorbing material without applying it to the outer-side principal surface of the supporting substrate 2a.

The thermoelectric power generation module shown in FIG. 2 includes a plate-shaped supporting member 4 for dissipating heat mounted to an outer-side principal surface of the other supporting substrate 2b of the pair of supporting substrates 2. The plate-shaped supporting member 4 is provided for increasing the rigidity of the thermoelectric power generation module. Examples of materials for forming the plate-shaped supporting member 4 include ceramics, metal, and resin. However, as mentioned below, in order to make the heat-dissipation amount larger and obtain a larger temperature difference, it is desirable to use materials having high thermal conductivity, such as aluminum or copper.

Further, in the thermoelectric power generation module shown in FIG. 2, in order to make the temperature difference larger between an upper side and a lower side, a heat dissipating member is mounted to the outer-side principal surface of the other supporting substrate 2b of the pair of supporting substrates 2 with the plate-shaped supporting member 4 being disposed therebetween. More specifically, as a heat dissipating member, a heat exchanger 8 including a metallic heat dissipating substrate 8a and metallic fins 8b is mounted to the plate-shaped supporting member 4. As materials of the heat exchanger 8, for example, ceramics or metallic materials, such as copper or aluminum, having high thermal conductivity that is higher than the thermal conductivity of the heat collecting member 3 are used. The heat exchanger 8 makes it possible to increase the rigidity of the supporting substrate 2 and at the same time increase heat dissipation, and to further reduce the temperature of a low-temperature portion. In particular, it is possible to obtain a high heat dissipation effect by providing the metallic fins 8b.

As the heat dissipating member, anything that dissipates heat may be used. The heat dissipating member may be a water-cooling heat pipe or an air-cooling heat-dissipating fin. The heat dissipating member may be directly mounted to the outer-side principal surface of the supporting substrate 2b without disposing the plate-shaped supporting member 4 therebetween. However, from the viewpoint of facilitating mounting, it is desirable that, as in the embodiment, the heat dissipating member be mounted to the outer-side principal surface of the supporting substrate 2b with the plate-shaped supporting member 4 being disposed therebetween.

The above-described thermoelectric power generation module can be manufactured, for example, as follows.

First, a wire conductor 6 is formed at a principal surface of one of supporting substrates 2 (2a, 2b). Here, examples of methods of forming the wire conductor 6 at the principal surface of one of the supporting substrates 2 (2a, 2b) include (1) metallizing a surface of an insulating material, and joining a metallic chip using, for example, solder, (2) printing a metallic paste onto a surface of an insulating material for firing, (3) subjecting the entire surface of an insulating material to metal plating, and forming a metal-plated electrode pattern on the surface of the insulating material using a photoresist, (4) press-contacting metallic plates against both surfaces of an insulating material, and forming a metallic electrode pattern on one surface or metallic electrode patterns on both of the surfaces using a photoresist, and (5) providing an insulating layer on a surface of a conductive material and forming a metallic electrode pattern.

Next, thermoelectric elements 5 (N-type thermoelectric elements 5a and P-type thermoelectric elements 5b) and the substrate 2 are joined to each other. More specifically, solder paste or an adhesive material containing solder paste is applied to at least a portion of the wire conductor 6 at the supporting substrate 2a, to form a solder layer. Here, as the applying method, it is desirable to use a screen printing method using a metal mask or a screen mesh from the viewpoints of costs and mass productivity. As the solder paste, for example, a solder paste formed of 95Sn-5Sb may be used.

Then, the thermoelectric elements 5 are arranged at a surface of the wire conductor 6 to which the solder has been applied. Two types of thermoelectric elements, the N-type thermoelectric elements 5a and the P-type thermoelectric elements 5b, need to be arranged as the thermoelectric elements 5. As the joining method, any method may be used as along as it is a publicly known technique. However, it is desirable to use a method in which, after the N-type thermoelectric elements 5a and the P-type thermoelectric elements 5b have been arranged by a transfer system, they are transferred and arranged at the supporting substrate 2a because this system is a simple system. In the transfer system, the N-type thermoelectric elements 5a and the P-type thermoelectric elements 5b are transferred to a jig including arrangement holes while separately vibrating the N-type thermoelectric elements 5a and the P-type thermoelectric elements 5b.

After arranging the thermoelectric elements 5 (N-type thermoelectric elements 5a and P-type thermoelectric elements 5b) at the supporting substrate 2a, the supporting substrate 2b at the opposite side is set at top surfaces of the thermoelectric elements 5 (N-type thermoelectric elements 5a and the P-type thermoelectric elements 5b).

More specifically, the supporting substrate 2b where solder has been applied to a surface of a wire conductor 6 is joined with solder to the top surfaces of the thermoelectric elements 5 (N-type thermoelectric elements 5a and P-type thermoelectric elements 5b) by a publicly known technique. As the joining method using solder, for example, heating using a reflow oven or a heater may be used. However, when a resin is used in the supporting substrate 2, it is desirable to perform heating while applying a stress to upper and lower surfaces from the viewpoint of increasing adhesion between the solder and the thermoelectric elements 5 (N-type thermoelectric elements 5a and P-type thermoelectric elements 5b).

Next, lead wires (not shown) for causing electric current to flow through the wire conductors 6 are joined using, for example, a soldering iron or laser. Here, after joining the lead wires, it is recommended that flux contained in the solder paste that is stuck on the thermoelectric elements (N-type thermoelectric elements 5a and P-type thermoelectric elements 5b) and the pair of supporting substrates 2 (2a, 2b) be cleaned by immersion in a cleaning liquid.

Next, a heat collecting member 3 is mounted to the supporting substrate 2a using, for example, a screw. When a heat absorbing material is to be applied to the outer-side principal surface of the supporting substrate 2a, for example, screen printing, spin coating, or a method of spreading a heat absorbing material during pressure-fixing by dispensation is used. When gaps (grooves 7 or concave portions) between the supporting substrate 2a and the heat collecting member 3 are to be filled with a heat absorbing material, screen printing or spin coating is used.

Lastly, the other supporting substrate 2b and a heat exchanger 8 are mounted with a plate-shaped supporting member 4 being disposed therebetween. More specifically, they are mounted by, for example, applying grease having high thermal conductivity.

By the above-described method, the thermoelectric power generation module according to the present invention can be formed.

### Example

The present invention is hereunder described in more detail using an example.

First, using a pair of supporting substrates, in which copper plates were bonded to outer-side principal surfaces of epoxy substrates provided with aluminum filler, a large 200-mm-square thermoelectric power generation module including wire conductors at inner-side principal surfaces of the supporting substrates was provided.

As thermoelectric elements, N-type thermoelectric elements formed of a thermoelectric material containing a solid solution of Bi₂Te₃ (bismuth telluride) and Bi₂Se₃ (bismuth selenide), and P-type thermoelectric elements formed of a thermoelectric material containing a solid solution of Bi₂Te₃ (bismuth telluride) and Sb₂Te₃ (antimony telluride) were used. Each thermoelectric element had a diameter of 1.8 mm, and a height of 1.6 mm. The thermoelectric elements were arranged vertically and horizontally side by side at an interval of 0.9 mm between the pair of supporting substrates, the total number of thermoelectric elements being 6400.

A metallic plate, formed of aluminum, for dissipating heat was attached to one of the supporting substrates of the module, and a heat exchanger including heat-dissipating aluminum fins was further mounted. Three such structures were provided. Thermoelectric power generation modules of three different types each having the aforementioned structure were provided. In the first type, a heat collecting member having a thickness of 3 mm and formed of glass was mounted to the high-temperature-side supporting substrate of the thermoelectric power generation module, with V-shaped grooves having a width of 0.3 mm and a depth of 100 μm being formed along portions between the thermoelectric elements in a surface of the heat collecting member contacting the supporting substrate. In the second type, a heat collecting member having a thickness of 3 mm, formed of glass, and not having V-shaped grooves formed therein was mounted to the high-temperature-side supporting substrate of the thermoelectric power generation module. In the third type, nothing was mounted to the high-temperature-side supporting substrate of the thermoelectric power generation module.

Using a lamp capable of simulating sunlight illumination, the three thermoelectric power generation modules were illuminated for one hour and unilluminated for 30 minutes repeatedly, until they were illuminated for 1000 hours. At the same time, heat dissipating fins were used for air-cooling with a fan, and a temperature difference of approximately 50° C. was provided and power generation amounts per hour were compared from accumulated power generation amounts.

The results showed that the power generation amount per hour of the thermoelectric power generation module not including a heat collecting member was 15 Wh, the power generation amount per hour of the thermoelectric power generation module including the heat collecting member was 20 Wh, and the power generation amount per hour of the thermoelectric power generation module including the heat collecting member with the grooves was 25 Wh. Therefore, the thermoelectric power generation module including the heat collecting member with the grooves had the highest power generation efficiency. The illumination of the thermoelectric power generation modules was similarly continued for up to 10,000 hours at most. A failure occurred due to broken wires in the thermoelectric power generation module not including a heat collecting member when the module was illuminated for 2000 hours, and in the thermoelectric power generation module including the heat collecting member not provided with grooves when the module was illuminated for 7000 hours. However, such a failure did not occur in the thermoelectric power generation module including the heat collecting member with the grooves.

### Reference Signs List

2, 2a, 2b supporting substrate

3 heat collecting member

4 plate-shaped supporting member

5 thermoelectric element

5a N-type thermoelectric element

5b P-type thermoelectric element

6 wire conductor

7 groove

8 heat exchanger

8a heat dissipating substrate

8b fin

1. A thermoelectric power generation module comprising:
a pair of supporting substrates arranged so as to that face each other;
wire conductors at inner-side principal surfaces, which face each other, of the pair of supporting substrates;
thermoelectric elements arranged between the inner-side principal surfaces, which face each other, of the pair of supporting substrates; and
a heat collecting member on an outer-side principal surface of one of the supporting substrates,
wherein there is a plurality of uneven portions or a plurality of grooves at a contact surface of the heat collecting member that contacts the supporting substrate.

2. The thermoelectric power generation module according to claim 1, wherein the heat collecting member comprises a transparent plate.

3. The thermoelectric power generation module according to claim 2, wherein the contact surface comprises a concave portion of facing a space between two of the thermoelectric elements.

4. The thermoelectric power generation module according to claim 2, wherein the transparent plate comprises a plurality of convex lens-like portions on a primary surface thereof and the portions disposed directly above the thermoelectric elements, respectively.

5. The thermoelectric power generation module according to claim 2, wherein a plurality of grooves are located at the contact surface of the transparent plate that contacts the porting, the plurality of grooves located along portions between the thermoelectric elements that are adjacent to each other.

6. The thermoelectric power generation module according to claim 1, wherein the outer-side principal surface of the one of the supporting substrates comprises a covering layer comprising a heat absorbing material.

7. The thermoelectric power generation module according to claim 1, wherein concave portions of the uneven portions or the grooves comprises a heat absorbing material therein.

8. The thermoelectric power generation module according to claim 2, wherein the transparent plate comprises a material having low thermal conductivity.

9. The thermoelectric power generation module according to claim 2, wherein a heat dissipating member is located on the outer-side principal surface of the other supporting substrate, the heat dissipating member comprising a material having high thermal conductivity that is higher than that of the transparent plate.

10. A thermoelectric module for generating power, comprising:
a first substrate comprising a first surface and a second surface opposing each other;
a second substrate substantially parallel to the first substrate, the second substrate comprising a third surface that faces the first surface;
thermoelectric elements between the first and third surfaces, electrically coupled one to another; and
a heat collecting member on the second surface, comprising a contact surface having uneven portions or grooves, wherein the contact surface is in contact with the second surface.
